(19) United States
(12) Patent Application Publication
(10) Pub. No.: US 2006/0205193 A1
(43) Pub. Date: Sep. 14, 2006

(54) Method for forming SiC-based film and method for fabricating semiconductor device

(75) Inventors: Ken Sugimoto, Kawasaki (JP); Yoshiyuki Ohkura, Kawasaki (JP); Hirofumi Watatani, Kawasaki (JP); Tamotsu Owada, Kawasaki (JP); Kengo Inoue, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/220,591

(22) Filed: Sep. 8, 2005

(30) Foreign Application Priority Data
Mar. 9, 2005 (JP) 2005-065432

(51) Int. Cl. H01L 21/26; H01L 21/42

(52) U.S. Cl. 438/513

(57) ABSTRACT

The method for forming an SiC-based film comprises the step of generating NH₃ plasma on the surface of a substrate 20 in a chamber to make NH₃ plasma processing on the substrate 20, the step of removing reaction products containing nitrogen remaining in the chamber, and the step of forming an SiC film 34 on the substrate 20 by PECVD.

### CROSS-REFERENCE TO RELATED APPLICATIONS

This application is based upon and claims priority of Japanese Patent Application No. 2005-065432, filed on Mar. 9, 2005, the contents being incorporated herein by reference.

### BACKGROUND OF THE INVENTION

The present invention relates to a method for forming an SiC-based film and a method for fabricating a semiconductor device using an SiC-based film as a barrier film.

Recently, as the integration and the device density of semiconductor integrated circuits are increased, the multilayered structures of the semiconductor devices are more required. As the semiconductor integrated circuits are increasingly highly integrated, the problem of the interconnection delay that the signal propagation speed is lowered due to the increase of the capacitance between the interconnections connecting the semiconductor devices becomes conspicuous.

To decrease such interconnection delay, it is effective to lower the dielectric constant of the material of the insulation film between the interconnections, and various insulation film materials of low dielectric constants have been developed.

In the interconnection structures of semiconductor devices, generally, barrier films for preventing the diffusion of metals, such as copper, etc. of the interconnection layers into the inter-layer insulation films are formed. Silicon nitride film, etc. have been so far used as the barrier films. However, the relative dielectric constant of silicon nitride film is about 7.0, which is higher than that of silicon oxide film. It is expected that novel barrier films of lower dielectric constants, which take the place of the so far used barrier films of silicon nitride film, etc., are developed.

As an insulation film having a low dielectric constant and functioning as a barrier film, SiC-based films are noted. So far, various proposals intending the improvement, etc. of the characteristics of the SiC-based films have been made. Japanese published unexamined patent application No. 2003-124209, for example, discloses that SiC:H film is grown by the split growth, in which the growth and the stop of the growth of the SiC:H film are repeated, whereby the SiC:H film can have a relative dielectric constant of below about 3 including 3.

However, the use of the conventional SiC-based film as the barrier films have often decreased the yields of semiconductor devices or often lowered the reliability.

### SUMMARY OF THE INVENTION

An object of the present invention is to provide a method for forming an SiC-based film which can form SiC-based films of low dielectric constants having good characteristics as the barrier films, etc. for preventing the diffusion of metals of interconnection layers into inter-layer insulation films, and a method for fabricating a semiconductor device using as the barrier film the SiC-based film formed by the method for forming the SiC-based film.

According to one aspect of the present invention, there is provided a method for forming an SiC-based film comprising the steps of: generating NH₃ plasma on a surface of a substrate in a chamber to make NH₃ plasma processing on the substrate; removing reaction products containing nitrogen remaining in the chamber; and forming an SiC-based film on the substrate by PECVD in the chamber.

According to another aspect of the present invention, there is provided a semiconductor device comprising an SiC-based film a dielectric constant of which is below 4.0 and a nitrogen concentration in which is below 10³ counts/second including 10³ counts/second expressed in a secondary ion intensity analyzed by SIMS.

According to further another aspect of the present invention, there is provided a method for fabricating a semiconductor device comprising the steps of: forming a first insulation film over a semiconductor substrate with a device formed on; forming a first opening in the first insulation film; forming a first interconnection layer buried in the first opening; generating NH₃ plasma on a surface of the first interconnection layer in a chamber to make NH₃ plasma processing on the first interconnection layer; removing reaction products containing nitrogen remaining in the chamber; forming an SiC-based film on the first insulation film and the first interconnection layer by PECVD in the chamber; forming a second insulation film on the SiC-based film; and forming a second opening in the second insulation film and the SiC-based film down to the first interconnection layer.

According to the present invention, in continuously performing in one and the same chamber the step of making NH₃ plasma processing on a substrate and the step of forming an SiC-based film on the substrate by PECVD process, the step of removing reaction products containing nitrogen remaining in the chamber is provided between the NH₃ plasma processing step and the SiC-based film forming step, whereby the SiC-based film can have low dielectric constant, and small and uniform film thickness distribution. Accordingly, the SiC-based film can have good characteristics for the barrier film for preventing the diffusion of a metal of the interconnection layer, and semiconductor device characteristics and reliability can be improved.

### BRIEF DESCRIPTION OF THE DRAWINGS

FIG. 1 is a diagrammatic sectional view of the film forming apparatus used in the method for forming the SiC-based film according to a first embodiment of the present invention, which shows a structure thereof.

FIGS. 2A-2D are sectional views in the steps of the method for forming the SiC-based film according to the first embodiment of the present invention, which show the method.

FIG. 3 is a graph of the result of the analysis of the composition of the SiC films in the depth direction by SIMS (Part 1).

FIG. 4 is a graph of the result of the analysis of the composition of the SiC films in the depth direction by SIMS (Part 2).

FIGS. 5A-5D are sectional views of the semiconductor device in the steps of the method for fabricating the same according to a second embodiment of the present invention, which show the method (Part 1).

FIGS. 6A-6C are sectional views of the semiconductor device in the steps of the method for fabricating the same according to the second embodiment of the present invention, which show the method (Part 2).

FIGS. 7A and 7B are sectional views of the semiconductor device in the steps of the method for fabricating the same according to the second embodiment of the present invention, which show the method (Part 3).

FIGS. 8A and 8B are sectional views of the semiconductor device in the steps of the method for fabricating the same according to the second embodiment of the present invention, which show the method (Part 4).

FIGS. 9A and 9B are sectional views of the semiconductor device in the steps of the method for fabricating the same according to the second embodiment of the present invention, which show the method (Part 5).

### DETAILED DESCRIPTION OF THE INVENTION

### A First Embodiment

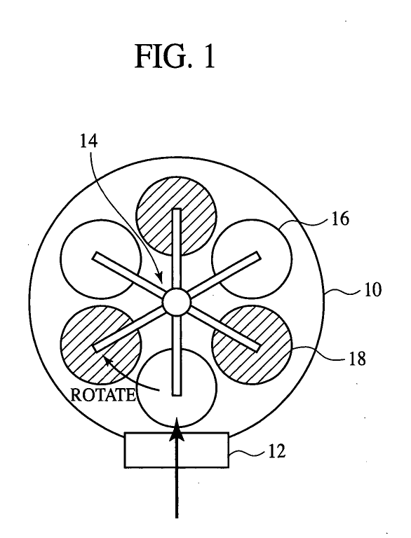

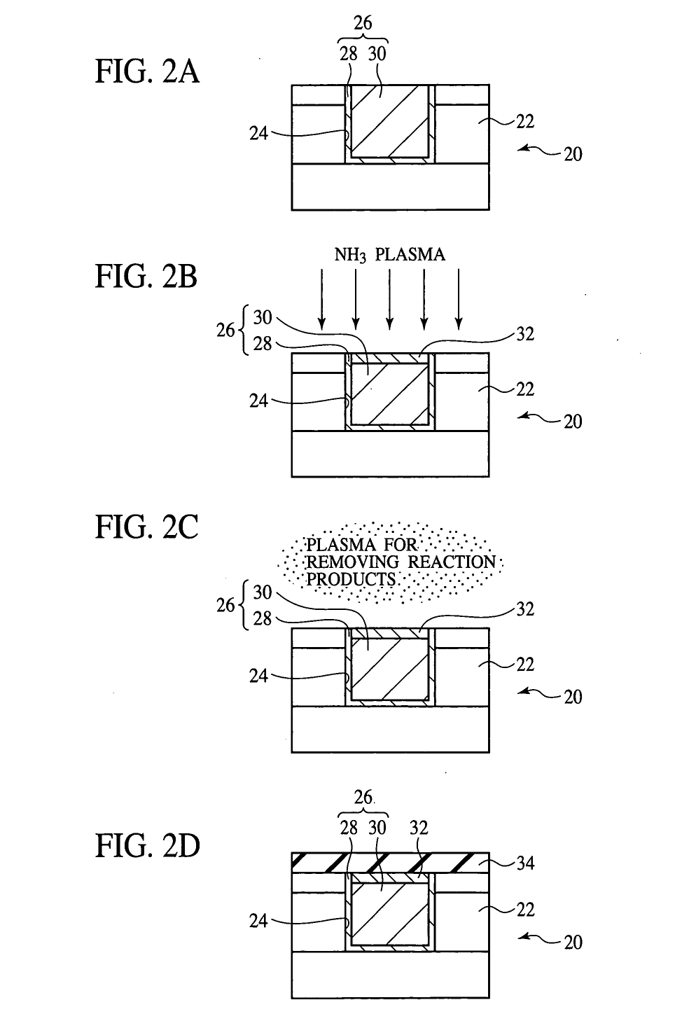

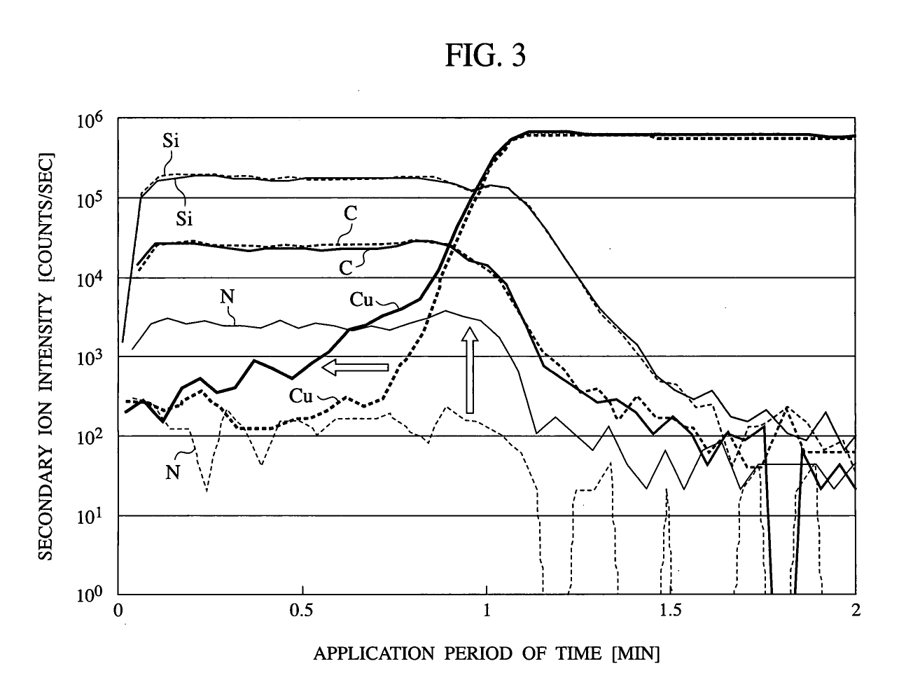

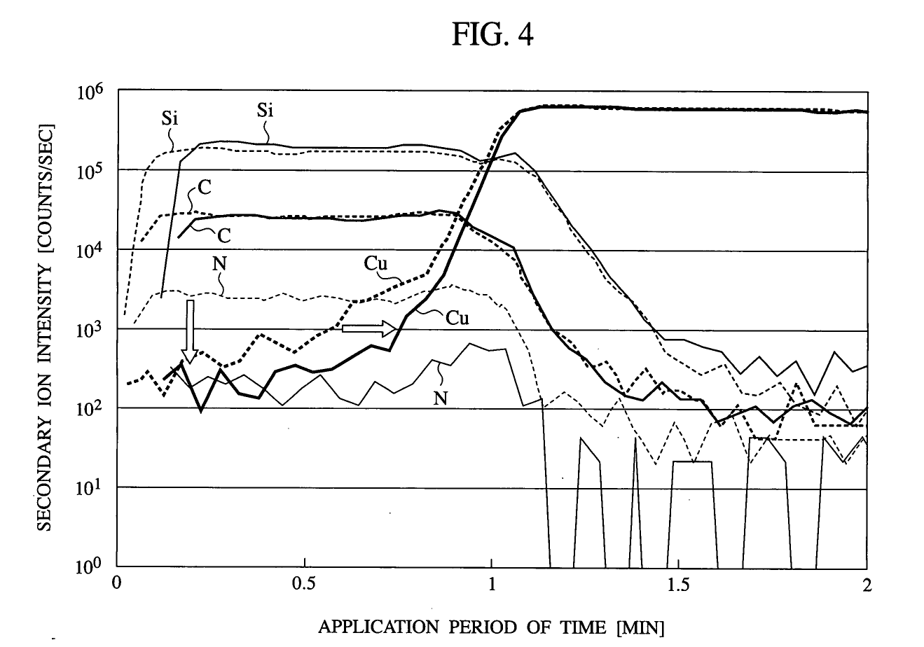

The method for forming the SiC-based film according to a first embodiment of the present invention will be explained with reference to FIGS. 1, 2A-2D, 3 and 4. FIG. 1 is a diagrammatic view of a film forming apparatus used in the method for forming the SiC-based film according to the present embodiment, which shows a structure thereof. FIGS. 2A-2D are sectional views in the steps of the method for forming the SiC-based film according to the first embodiment of the present invention, which show the method. FIGS. 3 and 4 are graphs of the results of analyzing the compositions of SiC films in the depth direction by SIMS.

The method for forming the SiC-based film according to the present embodiment forms an SiC film not doped with oxygen and having a relative dielectric constant smaller than 4.0 by PECVD (Plasma Enhanced Chemical Vapor Deposition) using as the raw material gas a single gas of 100% of methylsilane, such as tetramethylsilane or others.

First, the PECVD apparatus which is the film forming apparatus used in the method for forming the SiC-based film according to the present embodiment will be explained with reference to FIG. 1. FIG. 1 illustrates the film forming heads and the ammonia (NH₃) plasma processing heads in the chamber as viewed from above the film forming apparatus.

The chamber 10 of the film forming apparatus has a gate valve 12 for loading substrates, such as semiconductor wafers or others, for an SiC film to be formed on.

A plurality of substrates can be mounted on a stage (not illustrated) in the chamber 10. On the stage, a plurality of substrates are concentrically arranged with the substrate surfaces made horizontal.

Above the stage in the chamber 10, a plurality of NH₃ plasma processing heads 16 and a plurality of film forming heads 18 are suspended from a spindle 14, opposed to the substrates. The plurality of NH₃ plasma processing heads 16 and the plurality of film forming heads 18 are alternately arranged concentrically.

The NH₃ plasma processing heads 16 and the film forming heads 18 can be rotated by the spindle 14 in the direction of the arrangement and in the horizontal plane. Thus, in the chamber 10, first, the NH₃ plasma processing heads 16 are opposed to the substrates to make the NH₃ plasma processing on the substrates. Subsequently, the NH₃ plasma processing heads 16 and the film forming heads 18 are rotated by the spindle 14 to oppose the film forming heads 18 to the substrates the NH₃ plasma processing has been made. The film forming heads 18 opposed to the substrates the NH₃ plasma processing has been made form the SiC films on the substrates by PECVD.

As described above, the film forming apparatus used in the method for forming the SiC-based film according to the present embodiment can perform the NH₃ plasma processing as the pre-processing for the film formation by PECVD and the SiC film formation by PECVD continuously in one and the same chamber 10.

Next, the method for forming the SiC-based film according to the present embodiment will be explained with reference to FIGS. 1, 2A-2D, 3 and 4.

FIG. 2A illustrates the surface layer part of a substrate 20 for an SiC film to be formed on by the method for forming the SiC-based film according to the present embodiment. As illustrated, an interconnection layer 26 mainly of copper (Cu) is buried by CMP (Chemical Mechanical Polishing) in an interconnection trench 24 formed in the inter-layer insulation film 22. The interconnection layer 26 is formed of a barrier layer 28 of, e.g., a tantalum (Ta) film formed in the interconnection trench 24, and a Cu film 30 buried in the interconnection trench 24 with the barrier metal 28 formed in. The inter-layer insulation film 22 is formed over a substrate, such as a semiconductor wafer or others, with devices, such as transistors, etc. formed on.

First, the substrate 20 for an SiC film to be formed on is loaded into the chamber 10 of the film forming apparatus illustrated in FIG. 1 through the gate valve 12 to be mounted on the stage in the chamber 10.

Next, in the chamber 10, the NH₃ plasma processing head 16 is opposed to the substrate 20, and NH₃ plasmas are generated onto the surface of the substrate 20. The NH₃ plasma processing is thus made on the substrate 20 (see FIG. 2B). Conditions for the NH₃ plasma processing are, e.g., a 4 Torr internal pressure of the chamber 10, a 1200 W supplied power to the upper electrode, a 500 W supplied power to the lower electrode and a 3000 sccm NH₃ flow rate.

The NH₃ plasma reduces the oxide layer of the Cu formed on the surface of the interconnection layer 26 after planarized by CMP. Furthermore, the surface of the interconnection layer 26 is nitrided by the NH₃ plasma, and a nitride layer 32 of the Cu is formed on the surface of the interconnection layer 26.

After the NH₃ plasma processing, the inside of the chamber 10 is dry-cleaned with, e.g., monosilane (SiH₄)/dinitrogen monoxide (N₂O)-based plasmas (see FIG. 2C). The dry cleaning removes the reaction products including nitride generated in the chamber 10 by the NH₃ plasma processing from the inside of the chamber 10. The reaction products to be removed are NH₃, NH₂, NH, etc. Conditions for the dry cleaning are, e.g., a 300 sccm SiH₄ flow rate, a 9000 sccm N₂O flow rate and a 1500 sccm nitrogen (N₂) flow rate, respectively led into the chamber 10, a 2.4 Torr growth pressure and a 1000 W supplied power to the upper electrode.

Following the dry cleaning of the inside of the chamber 10, in the chamber 10, the film forming head 18 is opposed to the substrate 20 subjected to the NH₃ plasma processing to form the SiC film 34 of an average thickness of, e.g., below 30 nm including 30 nm on the inter-layer insulation film 22 and the interconnection layer 26 (see FIG. 2D). The raw material gas is, e.g., a single gas of 100% methylsilane, of e.g., tetramethylsilane or others. Conditions for forming the film are, e.g., a 5.5 Torr internal pressure of the chamber 10, a 400° C. substrate temperature, a 2500 W supplied power to the upper electrode and a 300 W supplied power to the lower electrode.

Thus, the SiC film 34 having a relative dielectric constant of below 4.0 is formed on the inter-layer insulation film 22 and on the interconnection layer 26. Specifically, the SiC film 34 of, e.g., a 3.7 relative dielectric constant is formed. The SiC film 34 functions as the barrier film for preventing the diffusion of the Cu of the interconnection layer.

As described above, the method for forming the SiC-based film according to the present embodiment is characterized mainly that the step of removing the reaction products including nitride remaining in the chamber 10 by the dry cleaning with plasmas is provided between the step of making the NH₃ plasma processing on the substrate 20 for the SiC film to be formed on in the chamber 10 and the step of forming the SiC film 34 on the substrate 20 by PECVD using as the raw material a single gas of 100% methylsilane in one and the same chamber 10 following the step of NH₃ plasma processing.

The SiC film used as the barrier film for preventing the diffusion of the metal of the interconnection material in the semiconductor device is required to have the dielectric constant further lowered.

An approach to lowering the dielectric constant of the insulation film is to lower the dielectric constant of the material itself of the insulation film or to decrease the film density of the insulation film. As a method for decreasing the film density of the SiC film, the method for increasing the concentration of the methyl group in the SiC film is known. So far, the inventors of the present application have confirmed that the SiC film of an about 4.5 relative dielectric constant can be formed by increasing the concentration of the methyl group in the SiC film.

Furthermore, the inventors of the present application have tried to further increase the concentration of the methyl group in the SiC film for the development of the SiC film of a relative dielectric constant of below 4.0 including 4.0. Specifically, while a mixed gas of methylsilane and carbon dioxide (CO₂) had been used as the raw material gas for forming the SiC film by PECVD, they tried to increase the concentration of the methyl group by using a single gas of 100% methylsilane. Resultantly, the SiC film of a 3.7 dielectric constant could be formed.

As described above, a single gas of 100% methylsilane is used as the raw material gas for forming the SiC film by PECVD, whereby the SiC film can be a low dielectric film whose relative dielectric constant is below 4.0. Accordingly, such SiC film can decrease the dielectric constant of the barrier film. However, simply using the SiC film formed by PECVD using as the raw material gas a single gas of 100% methylsilane as the barrier film of the interconnection layer formed mainly of Cu causes the following inconvenience.

After the interconnection layer mainly formed of Cu and before the barrier film is formed, the processing for reducing the surface of the interconnection layer is performed so as to remove the oxide layer of the Cu formed on the surface of the interconnection layer. The reduction processing uses hydrogen (H₂) plasma processing, NH₃ plasma processing or others. Such plasma processing is performed in the chamber for forming the barrier film usually prior to forming the barrier film. It has been reported that the NH₃ plasma processing not only reduces and removes the oxide layer formed on the surface of the interconnection layer, but also nitrides by the NH₃ plasmas the surface of the interconnection layer formed mainly of Cu, whereby the reliability of the semiconductor device is improved.

However, when the SiC film is formed by PECVD using a simple single gas of 100% methylsilane as the raw material gas after the NH₃ plasma processing, the film thickness distribution of the SiC film has been much deteriorated. The refractive index of the SiC film was also much changed. According to the experiments of the inventors of the present application, when the SiC film of a 30 nm-average film thickness is formed, the film thickness distribution of the SiC film formed without the NH₃ plasma processing was 3%, but the film thickness distribution of the SiC film formed with the NH₃ plasma processing was 18%. The refractive index of the SiC film formed without the NH₃ plasma processing was 1.82, but the refractive index of the SiC film formed with the NH₃ plasma processing was 1.67.

Especially the increase of the film thickness distribution of the SiC film as the barrier film much influences the fabrication yield. After the SiC film as a barrier film has been formed, an inter-layer insulation film is formed, a contact hole is formed by etching and a contact plug is formed, connected to a interconnection layer formed below the SiC film. At this time, when the SiC film is formed in a very disuniform film thickness distribution, the etching does not advance sufficiently in parts where the film thickness is large, and the SiC film is left. On the other hand, in parts where the film thickness is small, the etching advances excessively, and the interconnection layer is damaged. Both become causes for defective contact between the interconnection layer and the plug.

The inventors of the present application have noted the impurity concentration in the SiC film as a factor for causing the above-described film thickness distribution increase, etc. when the SiC film is formed by PECVD using as the raw material gas a single gas of 100% methylsilane after the NH₃ plasma processing.

FIG. 3 is a graph of the result of analysis of the composition of the SiC films in the depth direction by SIMS (Secondary Ion Mass Spectrometry). The application period of time of primary ions are taken on the horizontal axis of the graph, which corresponds to the depth of a sample, and the secondary ion intensity is taken on the vertical axis. Two samples were prepared for the SIMS analysis. One sample was prepared by forming the SiC film on a 60 nm-thickness Cu film formed on a silicon substrate after H₂ plasma processing, and the other sample was prepared by forming the SiC film on a 60 nm-thickness Cu film formed on a silicon substrate after NH₃ plasma processing. In both samples, the SiC film was formed in a 30 nm-average thickness by PECVD using a single gas of 100% tetramethylsilane as the raw material gas. The analysis conditions of the SIMS were as follows. For the applied primary ions, the ion species was Cs⁺, the acceleration energy was 50 keV, the incidence angle was 60° to the normal of the sample set at 0°, and the range of the primary ion cluster was a 350 μm×350 μm square. The analysis range of the sample was a 65 μm×65 μm square. The detected secondary ions were CsSi⁺, CsO⁺, CsC⁺, CsN⁺ and Cs₂H⁺. The charge correction was made by electron beam application. In the graph, the broken lines indicate the analysis result of the sample subjected to the H₂ plasma processing. In the graph, the solid lines indicate the analysis result of the sample subjected to the NH₃ plasma processing. The atom species indicated by the respective broken lines and the respective solid lines are led out near the respective lines.

Based on the graph of FIG. 3, it is found that the sample subjected to the NH₃ plasma processing has the nitrogen concentration in the SiC film which is about 10 times that of the sample subjected to the H₂ plasma processing.

It is found that in the sample subjected to the NH₃ plasma processing, the Cu in the Cu film below the SiC film is more largely diffused into the SiC film than in the sample subjected to the H₂ plasma processing. In the sample subjected to the NH₃ plasma processing, the diffusion distance of the Cu into the SiC film is about twice that of the sample subjected to the H₂ plasma processing.

When the NH₃ plasma processing was made, it is conceivable that traces of the reaction products generated by the NH₃ plasma processing were left in the chamber. The reaction products generated by the NH₃ plasma processing are substances, such as NH₃, NH₂, NH etc., which are expressed by NHₓ (x=1˜3). Such reaction products containing nitrogen will be mixed into the raw material gas when the SiC film is formed in one and the same chamber, following the NH₃ plasma processing, and resultantly the nitrogen will be contained as an impurity in the SiC film.

When the SiC film is formed, using the raw material gas a single gas of 100% methylsilane, even traces of impurities will much influence the film formation. Then, the inventors of the present application considered that the reaction products containing nitrogen generated by the NH₃ plasma processing are a cause for the film thickness distribution increase. In order to make this sure, they experimentally confirmed the influence on the SiC film by the absence and presence of the removal of the reaction products containing nitrogen remaining in the chamber after the NH₃ plasma processing.

In the experiments, two samples were prepared. One sample was prepared by forming the SiC film on a 60 nm-thickness Cu film formed on a silicon substrate without removing the reaction products remaining in the chamber after the NH₃ plasma processing. The other sample was prepared by forming the SiC film on a 60 nm-thickness Cu film formed on a silicon substrate with the reaction products remaining in the chamber removed after the NH₃ plasma processing. The reaction products were removed by dry cleaning using SiH₄/N₂O-based plasmas. In both samples, the SiC film was prepared in a 30 nm-average film thickness by PECVD using a single gas of 100% tetramethylsilane as the raw material gas. On these samples, the composition of the SiC film in the depth direction was analyzed by SIMS, and the film thickness distribution of the SiC film, etc. were measured.

FIG. 4 is a graph of the result of analysis of the composition of the SiC films in the depth direction by SIMS. In the graph, the broken lines indicate the analysis result of the sample without removing the reaction products after the NH₃ plasma processing. In the graph, the solid lines indicate the analysis result of the sample with the reaction products removed after the NH₃ plasma processing. The atom species indicated by the respective broken lines and the respective solid lines are led out near the respective lines. The analysis conditions of the SIMS were set to the same conditions as in the case of FIG. 3.

Based on the graph of FIG. 4, it is found that the sample having the reaction products removed by dry cleaning after the NH₃ plasma processing has the nitrogen concentration in the SiC film sufficiently decreased in comparison with the sample having the reaction products not removed after the NH₃ plasma processing. In the sample having the reaction products removed, the nitrogen concentration in the SiC film is about 1/10 of that in the sample having the reaction products not removed. That is, in the sample having the reaction products removed, the nitrogen concentration in the SiC film is decreased to substantially the same level as in the sample subjected to the H₂ plasma processing shown in FIG. 3.

It is found that in the sample having the reaction products removed by the dry cleaning after the NH₃ plasma processing, the diffusion of the Cu of the Cu film into the SiC film is sufficiently suppressed in comparison with that in the sample having the reaction products not removed. In the sample having the reaction products removed, the diffusion length of the Cu into the SiC film is about ½ of that in the sample having the reaction precuts not removed. That is, in the sample having the reaction products removed, the diffusion length of the Cu into the SiC film is shortened to substantially the same level as in the sample subjected to the H₂ plasma processing shown in FIG. 3.

On the other hand, the measurement results of the film thickness of the SiC film are as follows. The film thickness distribution of the SiC film of the sample having the reaction products not removed was 18%, while the film thickness distribution of the sample having the reaction products removed was decreased to 5%. Based on these results, it can be said that by removing the reaction products using the dry cleaning after the NH₃ plasma processing, the SiC film can be formed in a smaller and uniform film thickness distribution than by not removing the reaction products.

As for the refractive index of the SiC film, the refractive index of the sample having the reaction products not removed was 1.67, while the refractive index of the sample having the reaction products removed was 1.81.

Based on the above results, it has been confirmed that when the low dielectric SiC film of a dielectric constant of below 4.0 including 4.0 is formed by PECVD using as the raw material gas a single gas of 100% methylsilane, the reaction products containing nitrogen remaining in the chamber after the NH₃ plasma processing on the substrate are removed by dry cleaning, whereby the SiC film of a small and uniform film thickness distribution can be formed.

The method for forming the SiC-based film according to the present embodiment is based on the above-described knowledge. The method performs in one and the same chamber 10 the step of making NH₃ plasma processing on the substrate 20 and, following the NH₃ plasma processing step, the step of forming the SiC film 34 on the substrate 20 by PECVD using as the raw material gas a single gas of 100% methylsilane and includes between the NH₃ plasma processing step and the forming step of the SiC film 34 the step of removing the reaction products containing nitrogen remaining in the chamber by dry cleaning using plasmas. Thus, the SiC film 34 can have a small relative dielectric constant of below 4.0 including 4.0 and a small and uniform film thickness distribution. In forming the SiC film 34 relatively thin in, e.g., an average film thickness of below 30 nm including 30 nm, the SiC film 34 can have a small and uniform film thickness distribution. Accordingly, the SiC film 34 can have good characteristics as the barrier film for preventing the diffusion of the metal of the interconnection layer 26.

Furthermore, the surface of the interconnection layer 26 formed mainly of Cu on the substrate 20 is nitrided by the NH₃ plasma processing, and the nitride layer 32 of Cu is formed on the surface of the interconnection layer 26. Accordingly, the electromigration resistance of the interconnection layer 26 can be improved, and the characteristics and the reliability of the semiconductor device can be improved.

The SiC film formed by the method for forming the SiC-based film according to the present embodiment has the nitrogen concentration in the film sufficiently decreased. Specifically, the nitrogen concentration in the SiC film 34 is below 10³ counts/second including 10³ counts/second expressed in the secondary ion intensity analyzed by. SIMS. The value of the secondary ion intensity is given under analysis conditions of the SIMS that, for the applied primary ions, the ion species is Cs⁺, the acceleration energy is 50 keV, the incidence angle is 60° to the normal of the sample set at 0°, the range of the primary ion cluster is a 350 μm×350 μm square, the analysis range of the sample is a 65 μm×65 μm square, and the detected secondary ions are CsSi⁺, CsO⁺, CsC⁺, CsN⁺ and Cs₂H⁺.

### A Second Embodiment

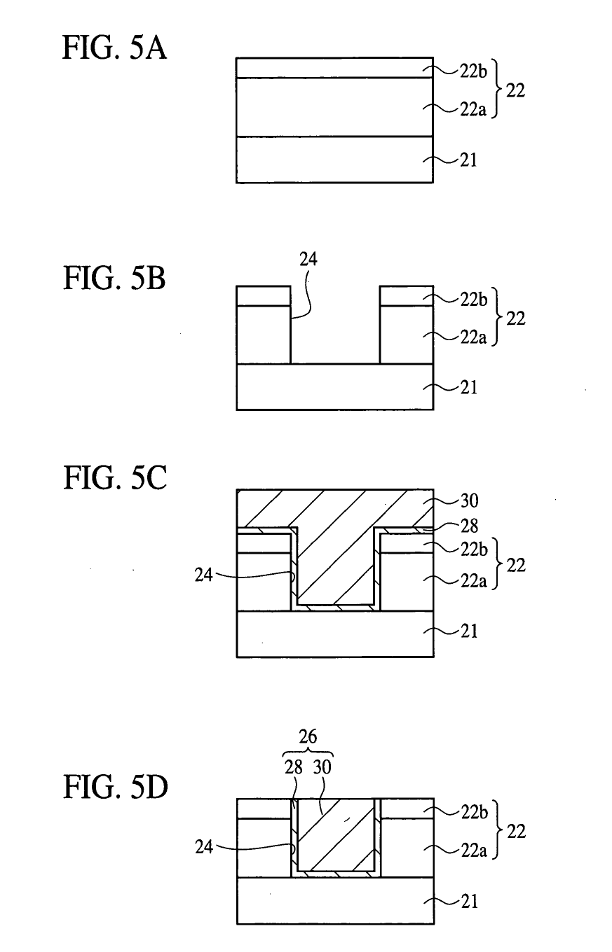

The method for fabricating the semiconductor device according to a second embodiment of the present invention will be explained with reference to FIGS. 5A-5D, 6A-6C, 7A-7B, 8A-8B and 9A-9B. FIGS. 5A-5D, 6A-6C, 7A-7B, 8A-8B and 9A-9B are sectional views of a semiconductor device in the steps of the method for fabricating the same according to the present embodiment, which show the method. The same members of the present embodiment as those of the method for fabricating the SiC-based film according to the first embodiment are represented by the same reference numbers not to repeat or to simplify their explanation.

The method for fabricating the semiconductor device according to the present embodiment fabricates a semiconductor device using the SiC film formed by the method for forming the SiC-based film according to the first embodiment as the barrier film for preventing the diffusion of a metal of an interconnection layer.

First, a device such as, e.g., a transistor, etc. is fabricated on a semiconductor substrate, such as a semiconductor wafer or others by the usual semiconductor device fabrication process. Next, an inter-layer insulation film 21 is formed on the semiconductor device with the device formed on.

On the inter-layer insulation film 21, an SiOC film 22a of, e.g., a 500 m-thickness is deposited by, e.g., CVD. Next, on the SiOC film 22a, a silicon oxide film 22b of, e.g., a 100 nm-thickness is deposited by, e.g., CVD. Thus, an inter-layer insulation film 22 of the SiOC film 22a and the silicon oxide film 22b sequentially laid the latter on the former is formed on the inter-layer insulation film 21 (see FIG. 5A).

Next, an interconnection trench 24 is formed in the inter-layer insulation film 22 by photolithography and dry etching (see FIG. 5B).

Then, on the entire surface, a barrier metal layer 28 of Ta film of, e.g., a 10 nm-thickness, and a Cu film of, e.g., a 40 nm-thickness are continuously deposited by, e.g., sputtering.

Next, as the Cu film formed on the barrier metal layer 28 as the seed, a Cu film is further deposited by electrolytic plating to form a Cu film 30 of, e.g., a 1 μm-total thickness (FIG. 5C).

Then, the Cu film 30 and the barrier metal layer 28 of the Ta film are polished by CMP to remove and planarize the Cu film 30 and the barrier metal layer 28. Thus, an interconnection layer 26 is formed of the barrier metal layer 28 of the Ta film for preventing the diffusion of the Cu, and the Cu film 30 forming the major part of the interconnection layer, buried in the interconnection trench 24 (see FIG. 5D).

Then, on the inter-layer insulation film 22 with the interconnection layer 26 buried in, the SiC film is formed by the method for forming the SiC-based film according to the first embodiment, as described below.

First, the semiconductor substrate which has been processed up to the interconnection layer 26 is loaded into the chamber 10 of the film forming apparatus illustrated in FIG. 1 and mounted on the stage in the chamber 10.

Next, in the chamber 10, the NH₃ plasma processing head 16 is opposed to the substrate, and NH₃ plasmas are generated on the surface of the substrate to make the NH₃ plasma processing on the substrate.

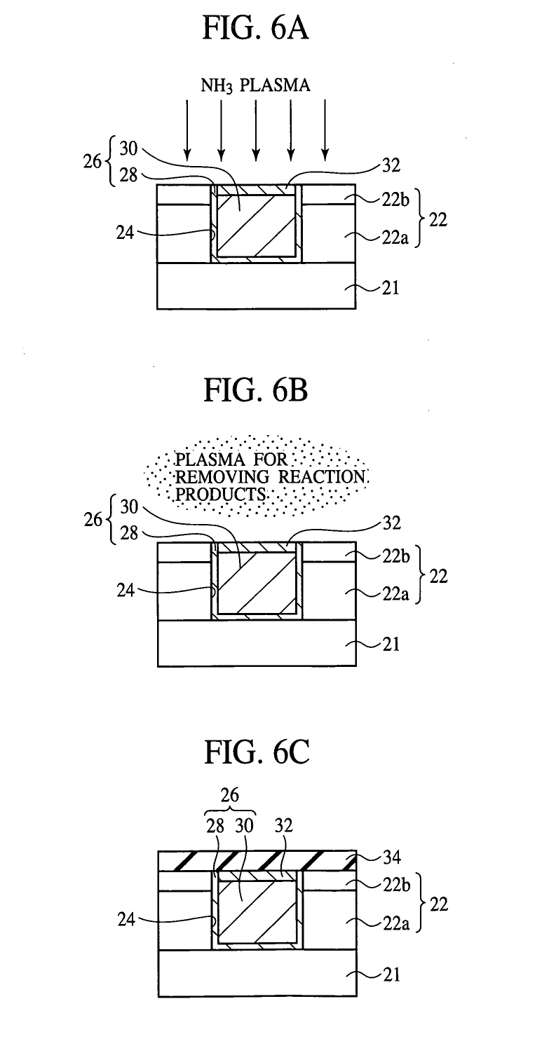

The NH₃ plasma processing reduces the Cu oxide layer formed on the surface of the interconnection layer 26 after the planarization by the CMP. Furthermore, the surface of the interconnection layer 26 is nitrided by the NH₃ plasma, and a Cu nitride layer 32 is formed on the surface of the interconnection layer 26 (see FIG. 6A).

After the NH₃ plasma processing, the inside of the chamber 10 is dry-cleaned with, e.g., SiH₄/N₂O-based plasmas (see FIG. 6B). The dry cleaning removes the reaction products containing nitrogen generated in the chamber 10 by the NH₃ plasma processing from the inside of the chamber 10. The reaction products to be removed are NH₃, NH₂, NH, etc.

After the inside of the chamber 10 has been dry-cleaned, the semiconductor substrate the NH₃ plasma processing has been made on is opposed to the film forming head 18 to continuously make the SiC film 34 of an average film thickness of, e.g., below 30 nm including 30 nm on the inter-layer insulation film 22 and the interconnection layer 26 (see FIG. 6C). As the raw material gas, a single gas of 100% methylsilane, e.g., tetramethylsilane or others is used. The relative dielectric constant of the formed SiC film 34 is below 4.0 including 4.0, specifically, e.g., 3.7.

Thus, by the method for forming the SiC-based film according to the first embodiment, the SiC film 34 as the barrier film for preventing the diffusion of the Cu of the interconnection layer 26 is formed on the inter-layer insulation film 22 and the interconnection layer 26.

Then, an SIOC film 36 of, e.g., a 300 nm-thickness is deposited on the SiC film 34 by, e.g., CVD.

Next, an SiC film 38 of, e.g., a 50 nm-thickness is deposited on the SIOC film 36 by, e.g., CVD.

Next, an SIOC film 40 of, e.g., a 200 nm-thickness is deposited on the SiC film 38 by, e.g., CVD.

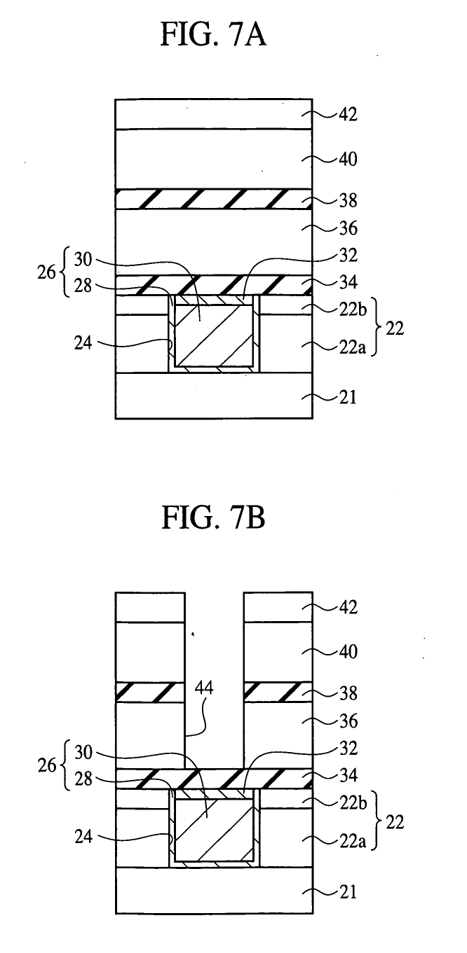

Next, a silicon oxide film 42 of, e.g., a 100 nm-thickness is deposited on the SIOC film 40 by, e.g., CVD (see FIG. 7A).

Next, by photolithography and dry etching, a via hole 44 is formed in the silicon oxide film 42, the SIOC film 40, the SiC film 38 and the SIOC film 36 positioned above the interconnection layer 26 (see FIG. 7B).

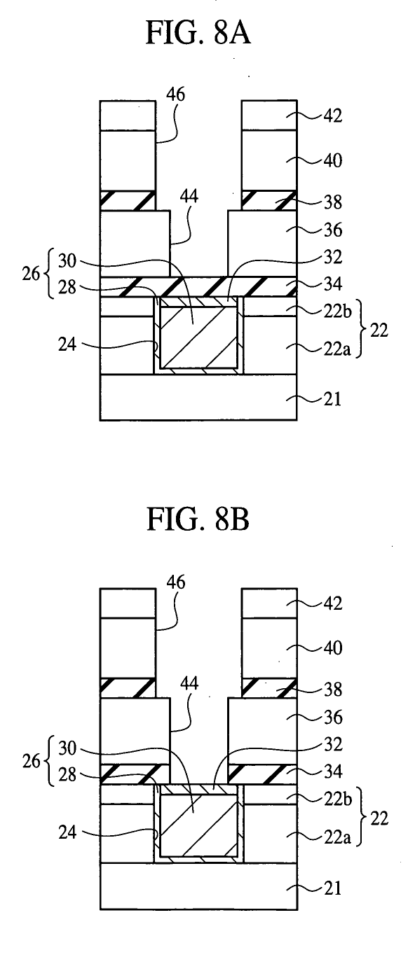

Next, by photolithography and dry etching, an interconnection trench 46 is formed in a region of the silicon oxide film 42, the SIOC film 40, and the SiC film 38, which contains the via hole 44 (see FIG. 8A).

Then, by dry etching, the SiC film 34 on the interconnection layer 26 exposed on the bottom of the via hole 44 is removed (see FIG. 8B). Thus, the via hole 44 arrives at the interconnection layer 26.

At this time, since the SiC film 34 is formed by the method for forming the SiC-based film according to the first embodiment, the SiC film 34 is formed in a small and uniform film thickness distribution. The etching advances accordingly homogeneously, which prevents the SiC film 34 from locally remaining or prevents the etching from locally excessively advancing to resultantly damaging the interconnection layer 26. Thus, the occurrence of the defective contact can be prevented and the reliability of a semiconductor device can be improved.

Then, on the entire surface, a barrier metal layer 48 of Ta film of, e.g., a 10 nm-thickness, and a Cu film of, e.g., a 40 nm-thickness are continuously deposited by, e.g., sputtering.

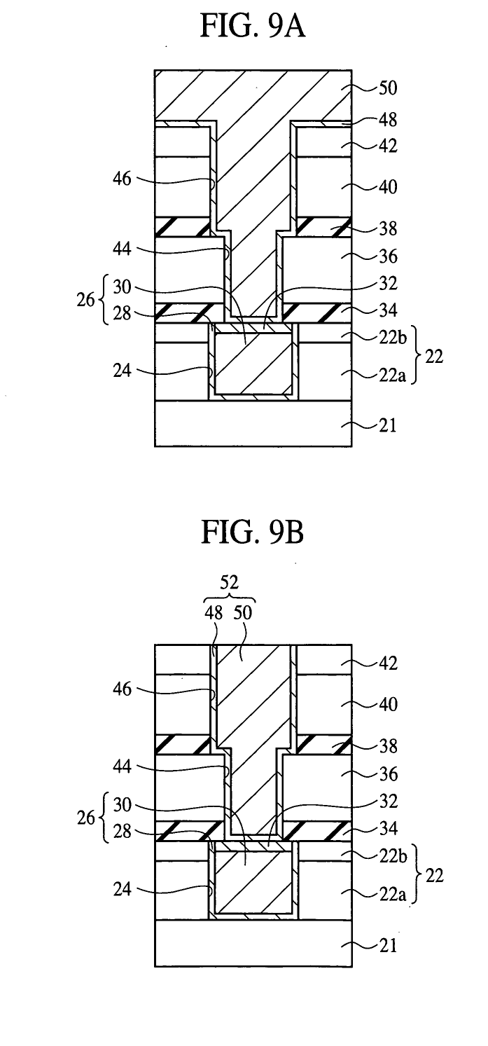

Next, as the Cu film formed on the barrier metal layer 48 as the seed, a Cu film is further deposited by electrolytic plating to form a Cu film 50 of, e.g., a 1 μm-total thickness (FIG. 9A).

Then, the Cu film 50 and the barrier metal layer 48 of the Ta film are polished by CMP to remove and planarize the Cu film 50 and the barrier metal layer 48. Thus, an interconnection layer 52 is formed of the barrier metal layer 48 of the Ta film for preventing the diffusion of the Cu, and the Cu film 50 forming the major part of the interconnection layer, buried in the interconnection trench 48 and the via hole 44 (see FIG. 9B). As described above, the SiC film 34 on the bottom of the via hole 44 is uniformly removed. Accordingly, the occurrence of the defective contact between the interconnection layer 26 and the interconnection layer 52 can be prevented.

Hereafter, the same steps as described above are repeated in accordance with a structure of a semiconductor device to be fabricated to thereby form a multilayer interconnection. As the barrier film to be formed on the inter-layer insulation film with the interconnection layer buried in, an SiC film can be suitably formed by the method for forming the SiC-based according to the first embodiment.

As described above, according to the present embodiment, in performing in one and the same chamber 10 the step of reducing and nitriding the surface of the interconnection layer 26 by the NH₃ plasma processing, and the step of forming, following the NH₃ plasma processing, the SiC film 34 on the inter-layer insulation film 22 and the interconnection layer 26 by PECVD using as the raw material gas a single gas of 100% methylsilane, the reaction products containing nitrogen remaining in the chamber 10 are removed by dry cleaning using plasmas between the step of the NH₃ plasma processing and the step of forming the SiC film 34, whereby the SiC film 34 can have a small relative dielectric constant of below 4.0 including 4.0 and have a small and uniform film thickness distribution. Accordingly, the characteristics and the reliability of a semiconductor device can be improved.

### Modified Embodiments

The present invention is not limited to the above-described embodiments and can cover other various modifications.

For example, in the above-described embodiments, the reaction products containing nitrogen generated in the chamber 10 by the NH₃ plasma processing are removed from the inside of the chamber 10 by the dry cleaning using SiH₄/N₂O-based plasmas. However, the plasmas used in the dry cleaning are not limited to SiH₄/N₂O-based plasmas. For example, hexafluoroethane (C₂F₆)/oxygen (O₂)-based plasmas, octafluoropropane (C₃F₈)/O₂-based plasmas, SiH₄/O₂-based plasmas, SiH₄/CO₂-based plasmas, SiH₄/NH₃-based plasmas, etc. may be used for the dry cleaning.

In the above-described embodiments, the reaction products containing nitrogen generated in the chamber 10 by the NH₃ plasma processing are removed from the inside of the chamber 10 by the dry cleaning. However, the reaction products may not be removed essentially by the dry cleaning.

For example, the reaction products may be removed by evacuating the inside of the chamber 10 to decrease the pressure in the chamber 10 further from a pressure after the NH₃ plasma processing. For example, an about 4 Torr pressure in the chamber 10 after the NH₃ plasma processing is decreased to about 0.5 Torr for removing the reaction products.

The reaction products may be removed by purging the inside of the chamber 10 with an inert gas after the NH₃ plasma processing. The inert gas can be, e.g., Ar gas, nitrogen gas or others. The purging period of time is, e.g., about 5 minutes, and the quantity of the inert gas for the purge is, e.g., 3000 cc.

The reaction products may be removed by a suitable combination of the above-described methods for removing the reaction products.

In the above-described embodiments, the raw material gas for forming the SiC film 34 is tetramethylsilane. However, the raw material gas is not limited to tetramethylsilane and can be methylsilane, such as trimethylsilane, dimethylsilane, monomethylsilane.

In the above-described embodiments, the SiC film 34 is formed by PECVD using as the raw material a single gas of 100% methylsilane. However, the present invention is applicable widely to forming SiC-based films, such as oxygen doped SiC film, etc. For example, the present invention is applicable to forming an oxygen doped SiC film by PECVD using as the raw material gas a mixed gas of CO₂ and methylsilane, such as tetramethylsilane or others.

In the above-described embodiments, the film forming apparatus illustrated in FIG. 1 including a plurality of NH₃ plasma processing heads 16 and a plurality of film forming heads 18 in one and the same chamber 10, but the constitution of the film forming apparatus is not essentially limited to the constitution as illustrated in FIG. 1. The film forming apparatus used in the method for forming the SiC-based film according to the present invention can be an apparatus which can continuously perform the NH₃ plasma processing and the film formation by PECVD in one and the same chamber.

What is claimed is:

1. A method for forming an SiC-based film comprising the steps of:
generating NH₃ plasma on a surface of a substrate in a chamber to make NH₃ plasma processing on the substrate;
removing reaction products containing nitrogen remaining in the chamber; and
forming an SiC-based film on the substrate by PECVD in the chamber.

2. A method for forming an SiC-based film according to claim 1, wherein
in the step of forming the SiC-based film, the SiC-based film is formed by PECVD using a raw material gas containing methylsilane gas.

3. A method for forming an SiC-based film according to claim 1, wherein
in the step of forming the SiC-based film, the SiC-based film is formed by PECVD using as a raw material gas a mixed gas of methylsilane and CO₂.

4. A method for forming an SiC-based film according to claim 2, wherein
the methylsilane is tetramethylsilane.

5. A method for forming an SiC-based film according to claim 3, wherein
the methylsilane is tetramethylsilane.

6. A method for forming an SiC-based film according to claim 1, wherein
in the step of removing the reaction products, the reaction products are removed by dry cleaning using plasma.

7. A method for forming an SiC-based film according to claim 2, wherein
in the step of removing the reaction products, the reaction products are removed by dry cleaning using plasma.

8. A method for forming an SiC-based film according to claim 3, wherein
in the step of removing the reaction products, the reaction products are removed by dry cleaning using plasma.

9. A method for forming an SiC-based film according to claim 1, wherein
in the step of removing the reaction products, the reaction products are removed by decreasing a pressure inside the chamber from a pressure after the step of making NH₃ plasma processing on the substrate.

10. A method for forming an SiC-based film according to claim 2, wherein
in the step of removing the reaction products, the reaction products are removed by decreasing a pressure inside the chamber from a pressure after the step of making NH₃ plasma processing on the substrate.

11. A method for forming an SiC-based film according to claim 3, wherein
in the step of removing the reaction products, the reaction products are removed by decreasing a pressure inside the chamber from a pressure after the step of making NH₃ plasma processing on the substrate.

12. A method for forming an SiC-based film according to claim 1, wherein
in the step of removing the reaction products, the reaction products are removed by purging the inside of the chamber with an inert gas.

13. A method for forming an SiC-based film according to claim 2, wherein
in the step of removing the reaction products, the reaction products are removed by purging the inside of the chamber with an inert gas.

14. A method for forming an SiC-based film according to claim 3, wherein
in the step of removing the reaction products, the reaction products are removed by purging the inside of the chamber with an inert gas.

15. A method for forming an SiC-based film according to claim 1, wherein
an interconnection layer is formed on the surface of the substrate, and
in the step of making NH₃ plasma processing on the substrate, a surface of the interconnection layer is reduced with NH₃ plasma.

16. A method for forming an SiC-based film forming method according to claim 15, wherein
in the step of making NH₃ plasma processing on the substrate, a nitride layer is formed on the surface of the interconnection layer by NH₃ plasma.

17. A semiconductor device comprising
an SiC-based film a dielectric constant of which is below 4.0 and a nitrogen concentration in which is below 10³ counts/second including 10³ counts/second expressed in a secondary ion intensity analyzed by SIMS.

18. A method for fabricating a semiconductor device comprising the steps of:
forming a first insulation film over a semiconductor substrate with a device formed on;
forming a first opening in the first insulation film;
forming a first interconnection layer buried in the first opening;
generating NH₃ plasma on a surface of the first interconnection layer in a chamber to make NH₃ plasma processing on the first interconnection layer;
removing reaction products containing nitrogen remaining in the chamber;
forming an SiC-based film on the first insulation film and the first interconnection layer by PECVD in the chamber;
forming a second insulation film on the SiC-based film; and
forming a second opening in the second insulation film and the SiC-based film down to the first interconnection layer.

19. A method for fabricating a semiconductor device according to claim 18, further comprising, after the step of forming the second opening, the step of
forming a second interconnection layer buried in the second opening.
